(19) United States
(12) Patent Application Publication
(10) Pub. No.: US 2016/0188490 A1
(43) Pub. Date: Jun. 30, 2016

(54) COST-AWARE PAGE SWAP AND REPLACEMENT IN A MEMORY

(71) Applicant: Intel Corporation, Santa Clara, CA (US)

(72) Inventor: Ahmad A. Samih, Austin, TX (US)

(21) Appl. No.: 14/583,343

(22) Filed: Dec. 26, 2014

(51) Int. Cl. G06F 12/12; G11C 7/10; G06F 12/08

(52) U.S. Cl. CPC G06F 12/122; G06F 12/0833; G11C 7/1072; G06F 12/128; G06F 2212/69; G06F 2212/62

(57) ABSTRACT

Memory eviction that recognizes not all evictions have an equal cost on system performance. A management device keeps a weight and/or a count associated with each portion of memory. Each memory portion is associated with a source agent that generates requests to the memory portion. The management device adjusts the weight by a cost factor indicating a latency impact that could occur if the evicted memory portion is again requested after being evicted. The latency impact is a latency impact for the associated source agent to replace the memory portion. In response to detecting an eviction trigger for the memory device, the management device can identify a memory portion having a most extreme weight, such as a highest or lowest value weight. The management device replaces the identified memory portion with a memory portion that triggered the eviction.

### FIELD

Embodiments of the invention are generally related to memory management, and more particularly to cost aware page swap and replacement in a memory.

### COPYRIGHT NOTICE/PERMISSION

Portions of the disclosure of this patent document may contain material that is subject to copyright protection. The copyright owner has no objection to the reproduction by anyone of the patent document or the patent disclosure as it appears in the Patent and Trademark Office patent file or records, but otherwise reserves all copyright rights whatsoever. The copyright notice applies to all data as described below, and in the accompanying drawings hereto, as well as to any software described below: Copyright © 2014, Intel Corporation, All Rights Reserved.

### BACKGROUND

When a memory device stores data near capacity or at capacity, it will need to replace data to be able to store new data in response to additional data access requests from running applications. Some running applications are more sensitive to latency while others are more sensitive to bandwidth constraints. A memory manager traditionally determines what portion of memory to replace or swap in an attempt to reduce the number of faults or misses. However, reducing the total number of faults or misses may not be best for performance, seeing that some faults are more costly than others from the point of view of the running application workload.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing a particular feature, structure, and/or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1A is a block diagram of an embodiment of a system that implements memory eviction with a cost-based factor.

FIG. 1B is a block diagram of an embodiment of a system that implements memory eviction at a memory controller with a cost-based factor.

FIG. 2 is a block diagram of an embodiment of a system that implements memory eviction with a cost-based factor in a multilevel memory system.

FIG. 3 is a block diagram of an embodiment of a system that implements memory eviction based on a count having an LRU factor and a cost-based factor.

FIG. 4 is a flow diagram of an embodiment of a process for managing eviction from a memory device.

FIG. 5 is a flow diagram of an embodiment of a process for selecting an eviction candidate.

FIG. 6 is a flow diagram of an embodiment of a process for managing an eviction count.

FIG. 7 is a block diagram of an embodiment of a computing system in which cost-based eviction management can be implemented.

FIG. 8 is a block diagram of an embodiment of a mobile device in which cost-based eviction management can be implemented.

Descriptions of certain details and implementations follow, including a description of the figures, which may depict some or all of the embodiments described below, as well as discussing other potential embodiments or implementations of the inventive concepts presented herein.

### DETAILED DESCRIPTION

As described herein, memory eviction accounts for the different costs of eviction on system performance. Instead of merely keeping a weight or a value based on recency and/or use of a particular portion of memory, the memory eviction can be configured to evict memory portions that have a lower cost impact on system performance. In one embodiment, a management device keeps a weight and/or a count associated with each memory portion, which includes a cost factor. Each memory portion is associated with an application or a source agent that generates requests to the memory portion. The cost factor indicates a latency impact on the source agent that could occur if an evicted memory portion is again requested after being evicted or a latency impact to replace the evicted memory portion. In response to detecting an eviction trigger for the memory device, the management device can identify a memory portion having a most extreme weight, such as a highest or lowest weight. The system can be configured to make a lowest weight or a highest weight correspond to a highest cost of eviction. In one embodiment, the management device keeps memory portions that have a higher cost of eviction, and replaces the memory portion having a lowest cost of eviction. Thus, the system can be configured to evict the memory portions that will have the least effect on system performance. In one embodiment, using the cost-based approach described can improve latency in a system that has latency-sensitive workloads.

It will be understood that different memory architectures can be used. Single level memories (SLMs) have a single level of memory resources. A memory level refers to devices that have the same or substantially similar access times. A multilevel memory (MLM) includes multiple levels of memory resources. Each level of the memory resources has a different access time, with faster memories closer to the processor or processor core, and slower memories further from the core. Typically, in addition to being faster the closer memories tend to be smaller and the slower memories tend to have more storage space. In one embodiment, the highest level of memory in a system is referred to as main memory, while the other layers can be referred to as caches. The highest level of memory obtains data from a storage resource.

The cost-based approach described herein can be applied to an SLM or an MLM. While architectures and implementations may differ, in one embodiment, eviction in an SLM can be referred to as occurring in connection with page replacement and eviction in an MLM can be referred to as occurring in connection with page swap. As will be understood by those skilled in the art, page replacement and page swap refer to evicting or removing data from a memory resource to make room for data from a higher level or from storage. In one embodiment, all memory resources in an SLM or an MLM are volatile memory devices. In one embodiment, one or more levels of memory include nonvolatile memory. Storage is nonvolatile memory.

In one embodiment, memory management associates a weight to every page or memory portion to implement a cost-aware page or portion replacement. It will be understood that implementing weights is one non-limiting example. Traditionally, weights associated with memory pages are derived solely from the recency information (e.g., LRU (least recently used) information only). As described herein, memory management can associate a weight or other count with every page based on recency information (e.g., LRU information) and modify or adjust the weight or count based on cost information. Ideally, pages or portions that are more recently accessed, and that are associated with high cost would not be selected for replacement or swap. Instead, the memory management would select an eviction candidate from a page that is not recent and also associated with low cost.

In one embodiment, the memory management generates a cost measurement that can be expressed as:

Weight=Recency+α(Cost)

The weight is the result to store or the count to use to determine candidacy for eviction. In one embodiment, the memory management computes Recency for a page or portion in accordance with a known LRU algorithm. In one embodiment, the memory management computes cost for a page or portion in accordance with an amount of parallelism for the source agent associated with the page or portion. For example, in one embodiment, the cost is inversely proportional to the number of requests made over a period of time, or a number of requests currently pending in a request queue. The factor α can be used to increase or reduce the weight of the cost-based factor relative to the recency factor. It will be seen that when α=0, the weight of a page or portion can be solely decided based on recency information.

In one embodiment, α is a dynamically adjustable factor. The value of a is should be trained to give the proper weight for the cost. In one embodiment, training is performed offline based on a list of applications running on a defined architecture to the find the proper value of α for specific pending queue counts, on average across all applications. In one embodiment, the value of a can be modified based on a performance or condition of the system that performs the cache management.

Reference to memory devices can apply to different memory types. Memory devices generally refer to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random access memory), or some variant such as synchronous DRAM (SDRAM). A memory subsystem as described herein may be compatible with a number of memory technologies, such as DDR3 (dual data rate version 3, original release by JEDEC (Joint Electronic Device Engineering Council) on Jun. 27, 2007, currently on release 21), DDR4 (DDR version 4, initial specification published in September 2012 by JEDEC), LPDDR3 (low power DDR version 3, JESD209-3B, August 2013 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5 (currently in discussion by JEDEC), WIO3 (Wide I/O 3, currently in discussion by JEDEC), HBM2 (HBM version 2), currently in discussion by JEDEC), and/or others, and technologies based on derivatives or extensions of such specifications.

In addition to, or alternatively to, volatile memory, in one embodiment, reference to memory devices can refer to a nonvolatile memory device whose state is determinate even if power is interrupted to the device. In one embodiment, the nonvolatile memory device is a block addressable memory device, such as NAND or NOR technologies. Thus, a memory device can also include a future generation nonvolatile devices, such as a three dimensional crosspoint memory device, or other byte addressable nonvolatile memory device. In one embodiment, the memory device can be or include multi-threshold level NAND flash memory, NOR flash memory, single or multi-level Phase Change Memory (PCM), a resistive memory, nanowire memory, ferroelectric transistor random access memory (FeTRAM), magnetoresistive random access memory (MRAM) memory that incorporates memristor technology, or spin transfer torque (STT)-M RAM, or a combination of any of the above, or other memory.

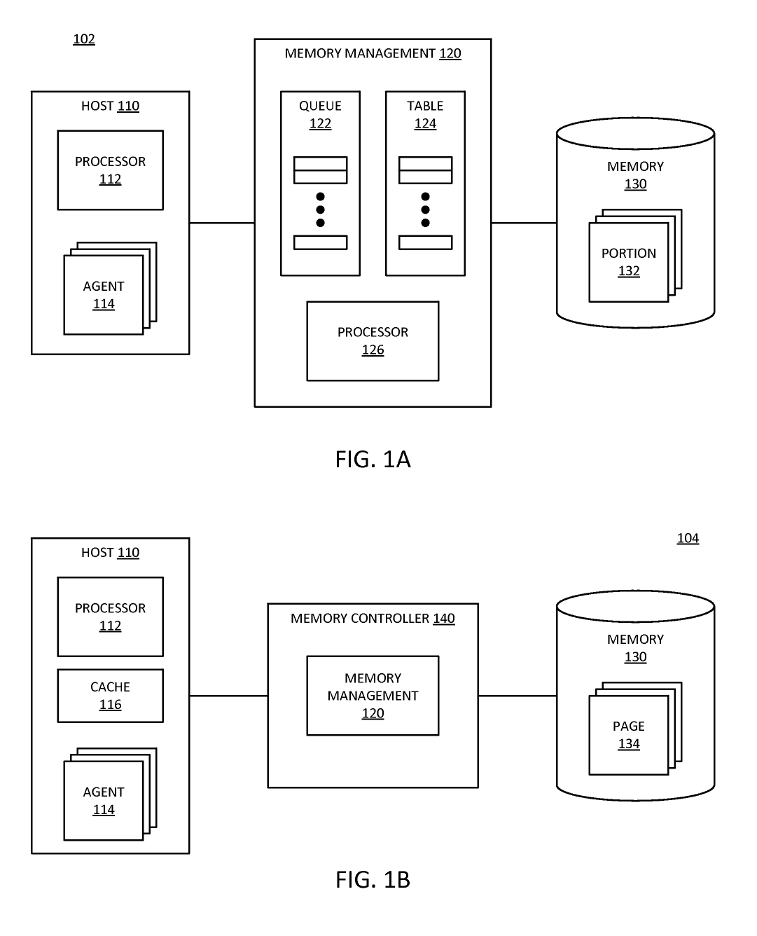

FIG. 1A is a block diagram of an embodiment of a system that implements memory eviction with a cost-based factor. System 102 represents elements of a memory subsystem. The memory subsystem includes at least memory management 120 and memory device 130. Memory device 130 includes multiple portions of memory 132. In one embodiment, each portion 132 is a page (e.g., 4k bytes in certain computing systems). In one embodiment, each portion 132 is a different size than a page. The page size can be different for different implementations of system 102. The page can refer to a basic unit of data referenced at a time within memory 130.

Host 110 represents a hardware and software platform for which memory 130 stores data and/or code. Host 110 includes processor 112 to execute operations within system 102. In one embodiment, processor 112 is a single-core processor. In one embodiment, processor 112 is a multicore processor. In one embodiment, processor 112 represents a primary computing resource in system 102 that executes a primary operating system. In one embodiment, processor 112 represents a graphics processor or peripheral processor. Operations by processor 112 generate requests for data stored in memory 130.

Agents 114 represent programs executed by processor 112, and are source agents for access requests to memory 130. In one embodiment, agents 114 are separate applications, such as end-user applications. In one embodiment, agents 114 include system applications. In one embodiment, agents 114 represent threads or processes or other units of execution within host 110. Memory management 120 manages access by host 110 to memory 130. In one embodiment, memory management 120 is part of host 110. In one embodiment, memory management 120 can be considered part of memory 130. Memory management 120 is configured to implement eviction of portions 132 based at least in part on a cost factor associated with each portion. In one embodiment, memory management represents a module executed by a host operating system on processor 112.

As illustrated, memory management 120 includes processor 126. Processor 126 represents hardware processing resources that enable memory management 120 to compute a count or weight for memory portions 132. In one embodiment, processor 126 is or is part of processor 112. In one embodiment, processor 126 executes an eviction algorithm. Processor 126 represents computing hardware that enables memory management 120 to compute information that is used to determine which memory portion 132 to evict in response to an eviction trigger. Thus, in one embodiment, processor 126 can be referred to as an eviction processor, referring to computing the counts or weights used to select an eviction candidate.

Memory management 120 bases eviction or swap from memory 130 at least in part on a cost to an associated agent 114 for the specific eviction candidate. Thus, memory management 120 will preferably evict or swap out a low cost page. In a latency-constrained system, high cost is associated with a memory portion (e.g., a page) that would cause a more significant performance hit for a miss of that memory portion. Thus, if the memory portion was evicted and a subsequent request required the memory portion to be accessed again, it would have a more significant impact on performance if it caused more delay than another memory portion.

In one embodiment, the cost is proportional to how much parallelism in requests is supported by the application. Certain memory requests require access to and operation on certain data prior to being able to request additional data, which increases how serial the requests are. Some memory requests can be performed in parallel with other requests, or they are not dependent on operation with respect to the memory portion prior to accessing another portion. Thus, parallel requests can have a lower cost relative to latency, and serial requests have higher latency cost.

Consider a stream of cache misses passed down a memory hierarchy. Memory management 120 can send parallel cache misses P1, P2, P3, and P4 down the memory hierarchy. The memory management can also send serial cache misses S1, S2, and S3. Parallel cache misses can be sent down the memory hierarchy in parallel and hence share the cost of the cache miss (i.e., hide the memory latency well). In contrast, the serial misses will be sent down the memory hierarchy serially and cannot share the latency. Thus, the serial misses are more sensitive to memory latency, making cache blocks accessed by these misses more costly than those accessed by parallel misses.

From the level of memory 130, if a page fault (for SLM) or a page miss (for MLM) occurs, the page fault/miss can share the cost of the page fault or page swap if there are many requests from the same source agent 114 pending. An agent 114 with a low number of requests would be more sensitive to the latency. Thus, agents 114 with higher memory level parallelism (MLP) can hide latency by issuing many requests to main memory 130. Portions or pages 132 associated with such agents 114 that are higher MLP applications should be less costly to replace than an agent 114 that is an application that does not show high level of MLP (such as pointer chasing applications). When MLP is low, the agent sends fewer parallel requests to memory 130, which makes the program more sensitive to latency.

Similar to what is described above, memory management 120 can implement cost-aware replacement by computing a cost or a weight associated with each portion 132. System 102 illustrates memory management 120 with queue 122. Queue 122 represents a pending memory access request from agents 114 to memory 130. The depth of queue 122 is different for different implementations. The depth of queue 122 can affect what scaling factor a (or equivalent for different weight calculations) should be used to add a cost-based contribution to the weight. In one embodiment herein, the expression eviction count can be used to refer to a value or a weight computed for a memory portion that includes a cost portion. In one embodiment, memory management 120 implements the equation described above, where a weight is computed as a sum of recency information and a scaled version of the cost. As described previously, in one embodiment, the cost factor is scaled in accordance with trained information for the architecture of system 102. It will be understood that the example does not represent all ways memory management 120 can implement cost-aware eviction/replacement. The trained information is information gathered during offline training of the system, where the system is tested under different loads, configurations, and/or operations to identify anticipated performance/behavior. Thus, the cost factor can be made to scale in accordance with observed performance for a specific architecture or other condition.

Recency information can include an indication of how recently a certain memory portion 132 was accessed by an associated agent 114. Techniques for keeping recency information are understood in the art, such as techniques used in LRU (least recently used) or MRU (most recently used) implementations, or similar techniques. In one embodiment, recency information can be considered a type of access history information. For example, access history can include an indication of when a memory portion was last accessed. In one embodiment, access history can include an indication of how frequently the memory portion has been accessed. In one embodiment, access history can include information that both indicates when the memory portion was last used, as well as how often the memory portion has been used (e.g., how “hot” a memory portion is). Other forms of access history are known.

In one embodiment, memory management 120 can dynamically adjust the scaling factor a based on an implementation of system 102. For example, memory management 120 may perform different forms of prefetching. In one embodiment, in response to different levels of aggressiveness in the prefetching, memory management 120 can adjust the scaling factor a to be used to compute cost to determine eviction candidates. For example, aggressive prefetching may provide a false appearance of MLP at the memory level.

In one embodiment, memory management 120 includes prefetch data in queue 122, which includes requests for data not yet requested by an application, but which is expected to be needed in the near future subsequent to the requested data. In one embodiment, memory management 120 ignores prefetch requests when computing a weight or count to use to determine eviction candidates. Thus, memory management 120 can treat prefetch requests as requests for purposes of computing a cost, or can ignore the prefetch requests for purposes of computing a cost. It may be preferable to have memory management 120 take prefetch requests into account when computing a weight if system 102 includes a well-trained prefetcher.

It will be understood that certain agents 114 may be CPU (central processing unit) bound applications with low count of memory references. In one embodiment, such agents will be perceived to have low MLP, which could result in a high cost. However, by including a recency factor in the count or weight, it will also be understood that such CPU bound applications can have a low recency component, which can offset the impact of the high cost. In one embodiment, the weight or count is a count that includes a value indicating how recently a memory portion 132 was accessed.

In one embodiment, table 124 represents information maintained by memory management 120 to manage eviction. In different implementations, table 124 can be referred to as an eviction table, as a weight table, as an eviction candidate table, or others. In one embodiment, table 124 includes a count or a weight for each memory portion 132 cached in memory 130. In one embodiment, reference could be made to memory management 120 “storing” certain pages or memory portions 132 of data. It will be understood that memory management 120 is not necessarily part of the memory where the actual data is stored. However, such a statement expresses the fact that memory management 120 can include table 124 and/or other mechanism to track the data elements stored in memory 130. Additionally, when items are removed from monitoring by memory management 120, the data is overwritten in memory 130 or at least is made available to be overwritten.

In one embodiment, memory management 120 computes a cost factor or a cost component of the weight by incrementing a cost counter by 1/N, where N is the number of parallel requests currently queued for the source agent 114 associated with the portion. In one embodiment, the memory management increments the cost by 1/N for every clock cycle of a clock associated with memory 130. Thus, for example, consider two agents 114, labeled for this example as Agent0 and Agent1. Assume that Agent0 has a single request pending in queue 122. Assume further that Agent 1 has 100 requests pending in queue 122. If the agents must wait 100 clock cycles for a return of data from a cache miss, both Agent0 and Agent1 will see 100 cycles. However, Agent1 has 100 requests pending, and so the latency can be seen as effectively approximately 1 cycle per request, and Agent0 sees an effective of approximately 100 cycles per request. It will be understood that different calculations can be used. While different calculations can be used, in one embodiment, memory management 120 computes a cost factor that indicates the ability of a source agent 114 to hide latency or latency due to waiting for service to a memory access request in operation of system 102.

FIG. 1B is a block diagram of an embodiment of a system that implements memory eviction at a memory controller with a cost-based factor. System 104 represents components of a memory subsystem, and can be one example of a system in accordance with system 102 of FIG. 1A. Like reference numbers between systems 104 and 102 can be understood to identify similar components, and the descriptions above can apply equally well to these components.

In one embodiment, system 104 includes memory controller, which is a circuit or chip that controls access to memory 130. In one embodiment, memory 130 is a DRAM device. In one embodiment, memory 130 represents multiple DRAM devices, such as all devices associated with memory controller 140. In one embodiment, system 104 includes multiple memory controllers, each associated with one or more memory devices. Memory controller 140 is or includes memory management 120.

In one embodiment, memory controller 140 is a standalone component of system 104. In one embodiment, memory controller 140 is part of processor 112. In one embodiment, memory controller 140 includes a controller or processor circuit integrated onto a host processor or host system on a chip (SoC). The SoC can include one or more processors as well as other components, such as memory controller 140 and possible one or more memory devices. In one embodiment, system 104 is an MLM system, with cache 116 representing a small, volatile memory resource close to processor 112. In one embodiment, cache 116 is located on-chip with processor 112. In one embodiment, cache 116 is part of an SoC with processor 112. For cache misses in cache 116, host 110 sends a request to memory controller 140 for access to memory 130.

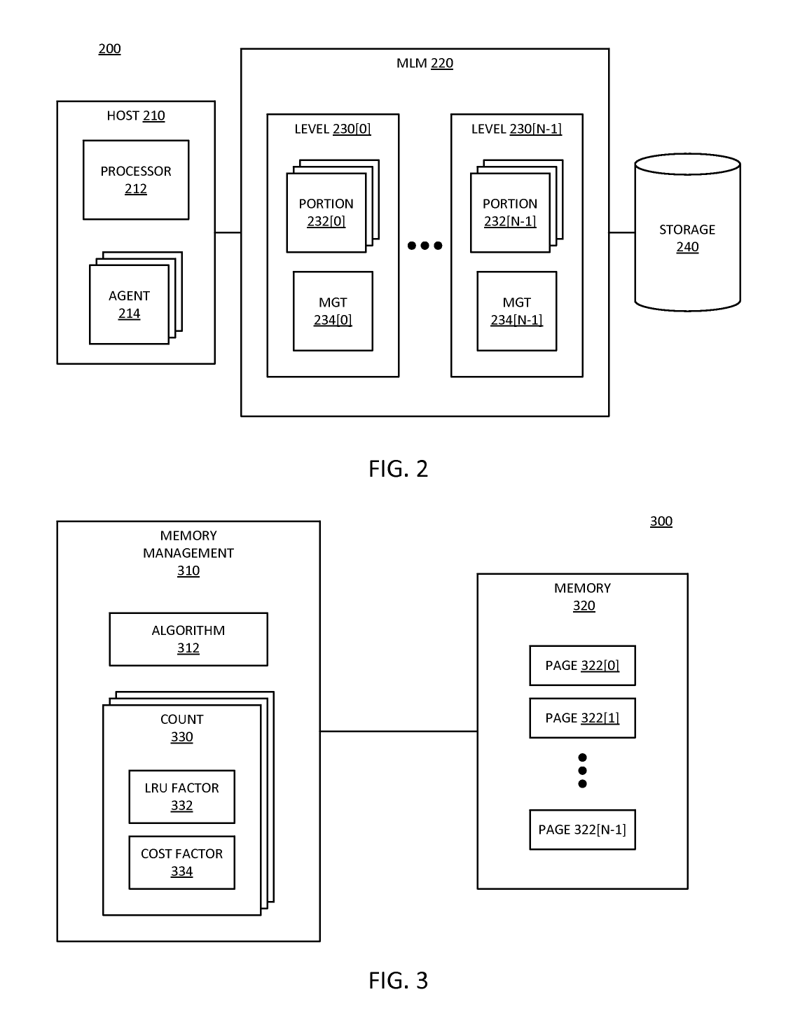

FIG. 2 is a block diagram of an embodiment of a system that implements memory eviction with a cost-based factor in a multilevel memory system. System 200 represents a multilevel memory system architecture for components of a memory subsystem. In one embodiment, system 200 is one example of a memory subsystem in accordance with system 102 of FIG. 1A, or system 104 of FIG. 1B. System 200 includes host 210, multilevel memory 220, and storage 240. Host 210 represents a hardware and software platform for which the memory devices of MLM 220 stores data and/or code. Host 210 includes processor 212 to execute operations within system 200. Operations by processor 212 generate requests for data stored in MLM 220. Agents 214 represent programs or source agents executed by processor 212, and their execution generates requests for data from MLM 220. Storage 240 is a nonvolatile storage resource from which data is loaded into MLM 220 for execution by host 210. For example, storage 240 can include a hard disk driver (HDD), semiconductor disk drive (SDD), tape drive, nonvolatile memory device such as Flash, NAND, PCM (phase change memory), or others.

Each of the N levels of memory 230 includes memory portions 232 and management 234. Each memory portion 232 is a segment of data that is addressable within the memory level 232. In one embodiment, each level 230 includes a different number of memory portions 232. In one embodiment, level 230[0] is integrated onto processor 212 or integrated onto an SoC of processor 212. In one embodiment, level 230[N-1] is main system memory (such as multiple channels of SDRAM), which directly requests data from storage 140 if a requests at level 230[N-1] results in a miss.

In one embodiment, each memory level 230 includes separate management 234. In one embodiment, management 234 at one or more memory levels 230 implements cost-based eviction determinations. In one embodiment, each management 234 includes a table or other storage to maintain a count or weight for each memory portion 232 stored at that memory level 220. In one embodiment, any one or more management 234 (such as management 234[N-1] of a highest level memory or main memory 230[N-1] accounts for access history to the memory portions 232 stored at that level of memory as well as cost information as indicated by a parallelism indicator.

FIG. 3 is a block diagram of an embodiment of a system that implements memory eviction based on a count having an LRU factor and a cost-based factor. System 300 illustrates components of a memory subsystem, including memory management 310 and memory 320. System 300 can be one example of a memory subsystem in accordance with any embodiment described herein. System 300 can be an example of system 102 of FIG. 1A, system 104 of FIG. 1B, or system 200 of FIG. 2. In one embodiment, memory 320 represents a main memory device for a computing system. In one embodiment, memory 320 stores multiple pages 322. Each page includes a block of data, which can include many bytes of data. Each of N pages 322 can be said to be addressable within memory 320.

In one embodiment, memory management 310 is or includes logic to manage the eviction of pages 322 from memory 320. In one embodiment, memory management 310 is executed as management code on a processor configured to execute the memory management. In one embodiment, memory management 310 is executed by a host processor or primary processor in the computing device of which system 300 is a part. Algorithm 312 represents the logical operations performed by memory management 310 to implement eviction management. The eviction management can be in accordance with any embodiment described herein of maintaining counts or weights, and determining an eviction candidate, and associated operations.

In one embodiment, algorithm 312 is configured to execute a weight calculation in accordance with the equation provided above. In one embodiment, memory management 310 includes multiple counts 330 to manage eviction candidates. Counts 330 can be the weights referred or some other count used to determine which page 322 should be evicted in response to a trigger to perform an eviction. In one embodiment, memory management 310 includes a count 330 for each page 322 in memory 320. In one embodiment, count 330 includes two factors or two components: LRU factor 332, and cost factor 334.

LRU factor 332 refers to an LRU calculation or other calculation that takes into account the recent access history of each page 322. Cost factor 334 refers to a count or computed value or other value used to indicate the relative cost of replacing an associated page. In one embodiment, algorithm 312 includes a scaling factor that enables memory management 310 to change weight or contribution of cost factor 334 to count 330. In one embodiment, memory management 310 keeps a counter (not specifically shown) for computing LRU factor 332. For example, in one embodiment, each time an associated page 322 is accessed memory management 310 can update LRU factor 332 with the value of the counter. Thus, a higher number can represent more recent use. In one embodiment, memory management 310 increments count 330 by an amount that accounts for a level of parallelism of a source agent associated with the page the count is for. For example, cost factor 334 can include an increment each clock cycle of one divided by a number of pending memory access requests. Thus, a higher number can represent higher cost to replace. Both examples for both LRU factor 332 and cost factor 334 are described in which higher values indicate a preference to keep a particular memory page 322. Thus, memory management 310 can be configured to evict a page with the lowest count 330. Additionally, it will be understood by those skilled in the art that each factor or component described could alternatively be oriented to the negative or to subtract or add a reciprocal, or perform other operation(s) that would make a low number indicate a preference to be kept, causing the page with the highest count 330 to be evicted.

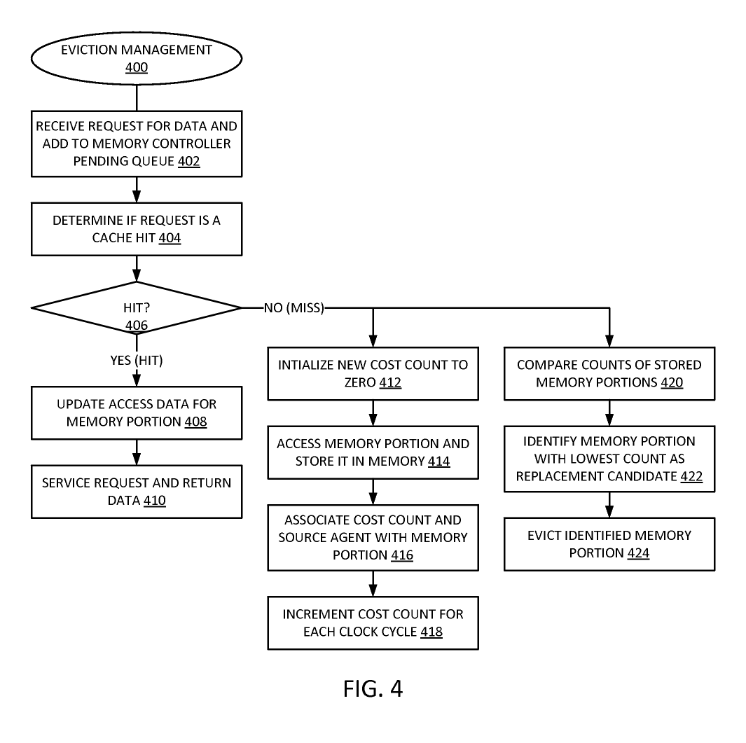

FIG. 4 is a flow diagram of an embodiment of a process for managing eviction from a memory device. Process 400 can be one example of a process for eviction management implemented in accordance with any embodiment of memory management herein. Process 400 illustrates one embodiment of how to measure the cost of a particular memory portion to enable cost-aware eviction and replacement.

In one embodiment, a memory controller receives a request for data and adds the request to a pending queue of the memory controller, 402. The memory controller can determine if the request is a cache hit, or if the request is for data that is already stored in memory, 404. If the request is a hit, 406 YES branch, in one embodiment, the memory controller can update the access history information for the memory portion, 408, and service and return the data, 410.

If the request is a miss, 406 NO branch, in one embodiment the memory controller can evict a memory portion from memory to make room for the requested portion to be loaded into memory. Thus, the requested memory portion can trigger eviction or replacement of a memory portion. In addition, the memory controller will access the requested data and can associate a count with the newly access memory portion for use in later determining an eviction candidate for a subsequent eviction request. For the requested memory portion, in one embodiment, the memory controller initializes a new cost count to zero, 412. Initializing a cost count to zero can include associating a cost count with the requested memory portion and resetting the value for the memory or table entry used for the cost count. In one embodiment, the memory controller can initialize the count to a non-zero value.

The memory controller accesses the memory portion from a higher level memory or from storage and stores it in the memory, 414. In one embodiment, the memory controller associates a cost count or a cost counter with the memory portion, 416. The memory controller can also associate the memory portion with a source agent that generates the request that caused the memory portion to be loaded. In one embodiment, the memory controller increments the cost count or cost counter for each clock cycle that the memory portion is stored in the memory, 418.

For determining an eviction candidate, in one embodiment, the memory controller compares the counts of memory portions stored in the memory, 420. The counts or weights can include an access history factor and a cost-based factor in accordance with any embodiment described herein. In one embodiment, the memory controller identifies the memory portion with a lowest count as a replacement candidate, 422. It will be understood that the memory controller can be configured to identify a memory portion with the other extreme count (i.e., a lowest count, or whatever extreme value corresponds to a lowest cost) as a candidate for eviction and replacement/swap. The memory controller can then evict the identified memory portion, 424. In one embodiment, the eviction of a memory portion from memory can occur prior to accessing a new portion to service or satisfy the request that caused the eviction trigger.

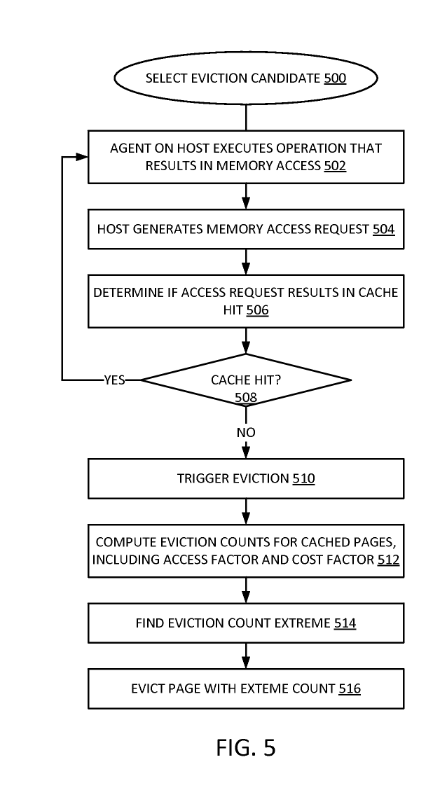

FIG. 5 is a flow diagram of an embodiment of a process for selecting an eviction candidate. Process 500 can be one example of a process by memory management to select a candidate for replacement or swap in accordance with any embodiment described herein. An agent executing on a host executes an operation that results in a memory access, 502. The host generates a memory access request, which is received by the memory controller or memory management, 504. The memory management determines if the request result in a cache hit, 506. If the request results in a hit, 508 YES branch, the memory management can service the request and return the data to the agent, which will keep on executing, 502.

In one embodiment, if the request results in a miss or fault, 508 NO branch, the memory management triggers an eviction of data from the memory to free space to load the request data, 510. In one embodiment, the memory management computes eviction counts for cached pages in response to the eviction trigger. Computing the eviction count can include computing a total weight for a page based on an access history or LRU count for the page adjusted by a cost factor for the associated agent, 512. In one embodiment, the memory management keeps a history count factor for each page, and cost factor information for each agent. The cost factor can then be accessed and added to a count for each page when determining which page to evict. In one embodiment, the memory management can first select among a predetermined number of candidates based on access history or LRU information alone, and then determine which of those candidates to evict based on cost. Thus, the eviction and replacement can be accomplished in multiple layers. The memory management can identify the most extreme eviction count (i.e., lowest or highest, depending on the system configuration), 514, and evict the page with the extreme count or weight, 516.

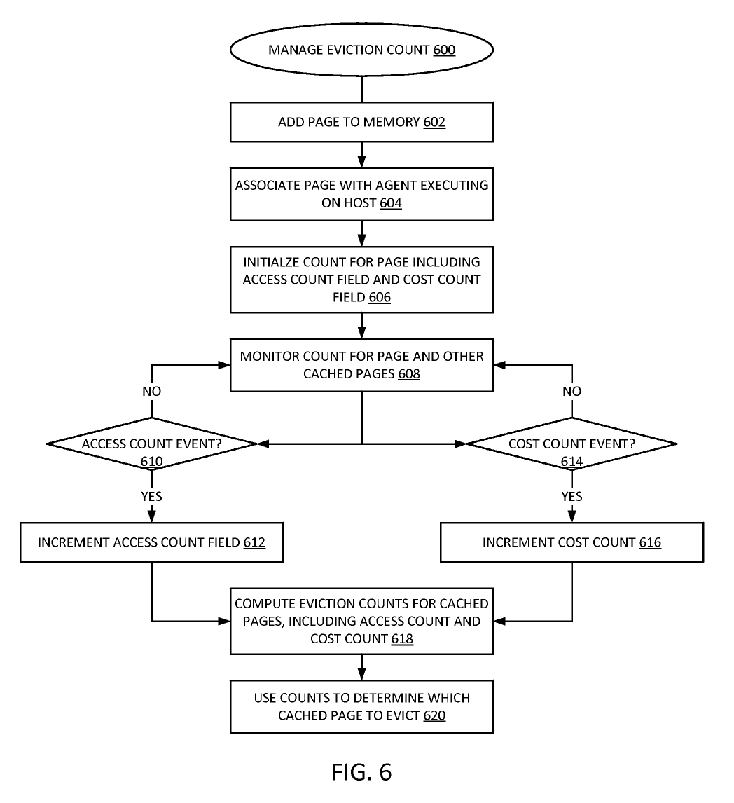

FIG. 6 is a flow diagram of an embodiment of a process for managing an eviction count. Process 600 can be one example of a process to manage a count used by memory management to determine eviction or page replacement/page swap, in accordance with any embodiment described herein. In conjunction with processing a request for data, memory management adds a page to memory, 602. In one embodiment, the memory management associates the page with an agent executing on the host, 604. The associated agent is the agent whose data request caused the page to be loaded into memory. Associating the agent with the page can include information in a table or tagging the page, or the use of other metadata.

The memory management initializes a count for the page, where the count can include an access history count field, and a cost count field, 606. The fields can be two different table entries for the page, for example. In one embodiment, the cost count field is associated with the agent (and thus shared with all pending pages for that agent), and added to the count when computed. The memory management can monitor the page and maintain a count for the page and other cached pages, 608.

If there is an access count event to update the access count field, 610 YES branch, the memory management can increment or otherwise update (e.g., overwrite) access count field information, 612. An access event can include access to the associated page. When there is no access count event, 610 NO branch, the memory management can continue to monitor for such events.

If there is a cost count event to update the cost count field, 614 YES branch, the memory management can increment or otherwise update (e.g., overwrite) cost count field information, 616. A cost count event can include a timer or clock cycling or reaching a scheduled value where counts are updated. When there is no cost count event, 610 NO branch, the memory management can continue to monitor for such events.

In one embodiment, the memory management updates eviction counts for cached pages, including access count information and cost count information, 618. The memory management uses the eviction count information to determine which cached page to evict in response to an eviction trigger, 620. In one embodiment, the computation mechanisms for updating or incrementing count information and the computation mechanisms for determining eviction candidates are separate computation mechanisms.

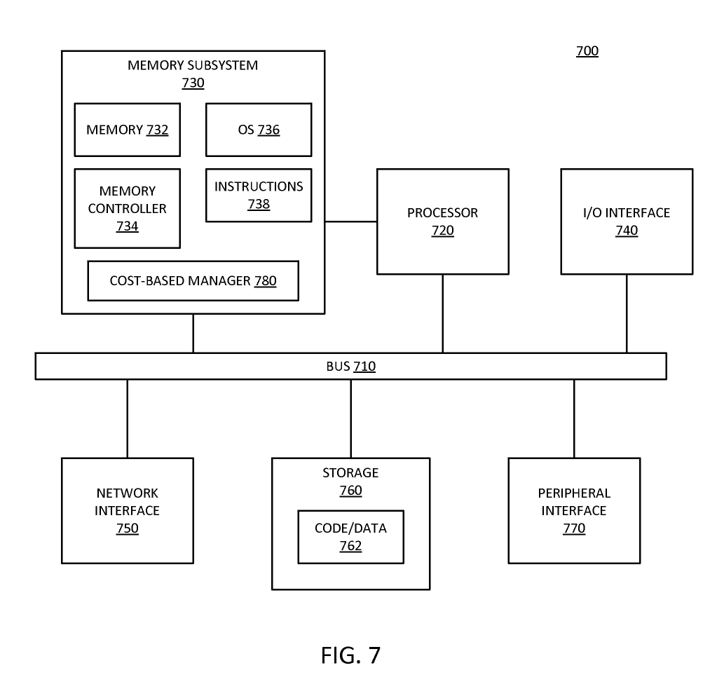

FIG. 7 is a block diagram of an embodiment of a computing system in which cost-based eviction management can be implemented. System 700 represents a computing device in accordance with any embodiment described herein, and can be a laptop computer, a desktop computer, a server, a gaming or entertainment control system, a scanner, copier, printer, routing or switching device, or other electronic device. System 700 includes processor 720, which provides processing, operation management, and execution of instructions for system 700. Processor 720 can include any type of microprocessor, central processing unit (CPU), processing core, or other processing hardware to provide processing for system 700. Processor 720 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Memory subsystem 730 represents the main memory of system 700, and provides temporary storage for code to be executed by processor 720, or data values to be used in executing a routine. Memory subsystem 730 can include one or more memory devices such as read-only memory (ROM), flash memory, one or more varieties of random access memory (RAM), or other memory devices, or a combination of such devices. Memory subsystem 730 stores and hosts, among other things, operating system (OS) 736 to provide a software platform for execution of instructions in system 700. Additionally, other instructions 738 are stored and executed from memory subsystem 730 to provide the logic and the processing of system 700. OS 736 and instructions 738 are executed by processor 720. Memory subsystem 730 includes memory device 732 where it stores data, instructions, programs, or other items. In one embodiment, memory subsystem includes memory controller 734, which is a memory controller to generate and issue commands to memory device 732. It will be understood that memory controller 734 could be a physical part of processor 720.

Processor 720 and memory subsystem 730 are coupled to bus/bus system 710. Bus 710 is an abstraction that represents any one or more separate physical buses, communication lines/interfaces, and/or point-to-point connections, connected by appropriate bridges, adapters, and/or controllers. Therefore, bus 710 can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus (commonly referred to as “Firewire”). The buses of bus 710 can also correspond to interfaces in network interface 750.

System 700 also includes one or more input/output (I/O) interface(s) 740, network interface 750, one or more internal mass storage device(s) 760, and peripheral interface 770 coupled to bus 710. I/O interface 740 can include one or more interface components through which a user interacts with system 700 (e.g., video, audio, and/or alphanumeric interfacing). Network interface 750 provides system 700 the ability to communicate with remote devices (e.g., servers, other computing devices) over one or more networks. Network interface 750 can include an Ethernet adapter, wireless interconnection components, USB (universal serial bus), or other wired or wireless standards-based or proprietary interfaces.

Storage 760 can be or include any conventional medium for storing large amounts of data in a nonvolatile manner, such as one or more magnetic, solid state, or optical based disks, or a combination. Storage 760 holds code or instructions and data 762 in a persistent state (i.e., the value is retained despite interruption of power to system 700). Storage 760 can be generically considered to be a “memory,” although memory 730 is the executing or operating memory to provide instructions to processor 720. Whereas storage 760 is nonvolatile, memory 730 can include volatile memory (i.e., the value or state of the data is indeterminate if power is interrupted to system 700).

Peripheral interface 770 can include any hardware interface not specifically mentioned above. Peripherals refer generally to devices that connect dependently to system 700. A dependent connection is one where system 700 provides the software and/or hardware platform on which operation executes, and with which a user interacts.

In one embodiment, memory subsystem 730 includes cost-based manager 780, which can be memory management in accordance with any embodiment described herein. In one embodiment, cost-based manager 780 is part of memory controller 734. Manager 780 keeps and computes a count or weight for each page or other memory portion stored in memory 732. The weight or count includes cost information for each page, where the cost indicates a performance impact for replacing the page in memory. The cost information can include or can be combined with access history information for the page. Based on the count or weight including the cost-based information, manager 780 can select a candidate for eviction from memory 732.

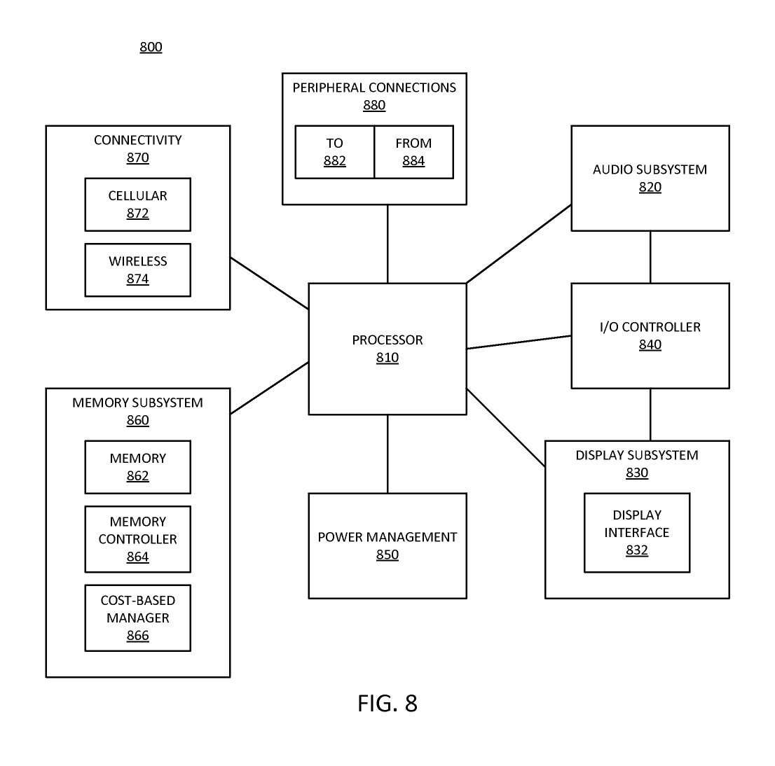

FIG. 8 is a block diagram of an embodiment of a mobile device in which cost-based eviction management can be implemented. Device 800 represents a mobile computing device, such as a computing tablet, a mobile phone or smartphone, a wireless-enabled e-reader, wearable computing device, or other mobile device. It will be understood that certain of the components are shown generally, and not all components of such a device are shown in device 800.

Device 800 includes processor 810, which performs the primary processing operations of device 800. Processor 810 can include one or more physical devices, such as microprocessors, application processors, microcontrollers, programmable logic devices, or other processing means. The processing operations performed by processor 810 include the execution of an operating platform or operating system on which applications and/or device functions are executed. The processing operations include operations related to I/O (input/output) with a human user or with other devices, operations related to power management, and/or operations related to connecting device 800 to another device. The processing operations can also include operations related to audio I/O and/or display I/O.

In one embodiment, device 800 includes audio subsystem 820, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into device 800, or connected to device 800. In one embodiment, a user interacts with device 800 by providing audio commands that are received and processed by processor 810.

Display subsystem 830 represents hardware (e.g., display devices) and software (e.g., drivers) components that provide a visual and/or tactile display for a user to interact with the computing device. Display subsystem 830 includes display interface 832, which includes the particular screen or hardware device used to provide a display to a user. In one embodiment, display interface 832 includes logic separate from processor 810 to perform at least some processing related to the display. In one embodiment, display subsystem 830 includes a touchscreen device that provides both output and input to a user. In one embodiment, display subsystem 830 includes a high definition (HD) display that provides an output to a user. High definition can refer to a display having a pixel density of approximately 100 PPI (pixels per inch) or greater, and can include formats such as full HD (e.g., 1080p), retina displays, 4K (ultra high definition or UHD), or others.

I/O controller 840 represents hardware devices and software components related to interaction with a user. I/O controller 840 can operate to manage hardware that is part of audio subsystem 820 and/or display subsystem 830. Additionally, I/O controller 840 illustrates a connection point for additional devices that connect to device 800 through which a user might interact with the system. For example, devices that can be attached to device 800 might include microphone devices, speaker or stereo systems, video systems or other display device, keyboard or keypad devices, or other I/O devices for use with specific applications such as card readers or other devices.

As mentioned above, I/O controller 840 can interact with audio subsystem 820 and/or display subsystem 830. For example, input through a microphone or other audio device can provide input or commands for one or more applications or functions of device 800. Additionally, audio output can be provided instead of or in addition to display output. In another example, if display subsystem includes a touchscreen, the display device also acts as an input device, which can be at least partially managed by I/O controller 840. There can also be additional buttons or switches on device 800 to provide I/O functions managed by I/O controller 840.

In one embodiment, I/O controller 840 manages devices such as accelerometers, cameras, light sensors or other environmental sensors, gyroscopes, global positioning system (GPS), or other hardware that can be included in device 800. The input can be part of direct user interaction, as well as providing environmental input to the system to influence its operations (such as filtering for noise, adjusting displays for brightness detection, applying a flash for a camera, or other features). In one embodiment, device 800 includes power management 850 that manages battery power usage, charging of the battery, and features related to power saving operation.

Memory subsystem 860 includes memory device(s) 862 for storing information in device 800. Memory subsystem 860 can include nonvolatile (state does not change if power to the memory device is interrupted) and/or volatile (state is indeterminate if power to the memory device is interrupted) memory devices. Memory 860 can store application data, user data, music, photos, documents, or other data, as well as system data (whether long-term or temporary) related to the execution of the applications and functions of system 800. In one embodiment, memory subsystem 860 includes memory controller 864 (which could also be considered part of the control of system 800, and could potentially be considered part of processor 810). Memory controller 864 includes a scheduler to generate and issue commands to memory device 862.

Connectivity 870 includes hardware devices (e.g., wireless and/or wired connectors and communication hardware) and software components (e.g., drivers, protocol stacks) to enable device 800 to communicate with external devices. The external device could be separate devices, such as other computing devices, wireless access points or base stations, as well as peripherals such as headsets, printers, or other devices.

Connectivity 870 can include multiple different types of connectivity. To generalize, device 800 is illustrated with cellular connectivity 872 and wireless connectivity 874. Cellular connectivity 872 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 874 refers to wireless connectivity that is not cellular, and can include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 880 include hardware interfaces and connectors, as well as software components (e.g., drivers, protocol stacks) to make peripheral connections. It will be understood that device 800 could both be a peripheral device (“to” 882) to other computing devices, as well as have peripheral devices (“from” 884) connected to it. Device 800 commonly has a “docking” connector to connect to other computing devices for purposes such as managing (e.g., downloading and/or uploading, changing, synchronizing) content on device 800. Additionally, a docking connector can allow device 800 to connect to certain peripherals that allow device 800 to control content output, for example, to audiovisual or other systems.

In addition to a proprietary docking connector or other proprietary connection hardware, device 800 can make peripheral connections 880 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other type.

In one embodiment, memory subsystem 860 includes cost-based manager 866, which can be memory management in accordance with any embodiment described herein. In one embodiment, cost-based manager 866 is part of memory controller 864. Manager 7866 keeps and computes a count or weight for each page or other memory portion stored in memory 862. The weight or count includes cost information for each page, where the cost indicates a performance impact for replacing the page in memory. The cost information can include or can be combined with access history information for the page. Based on the count or weight including the cost-based information, manager 866 can select a candidate for eviction from memory 862.

In one aspect, a method for managing eviction from a memory device includes: initializing a count for one of multiple memory portions in a memory device, including associating the count with a source agent that accesses the one memory portion; adjusting the count based on access to the one memory portion by the associated source agent; adjusting the count based on a dynamic cost factor for the associated source agent, where the dynamic cost factor represents a latency impact to performance of the source agent to replace the memory portion; and comparing the count to counts for others of the multiple portions to determine which memory portion to evict in response to an eviction trigger for the memory device.

In one embodiment, wherein the memory device comprises a main memory resource for a host system. In one embodiment, wherein the comparing comprise comparing with a memory controller device. In one embodiment, wherein initializing the count comprises initializing the count in response to receiving a request from a lower-level memory requesting data. In one embodiment, wherein comparing the count further comprises identifying for eviction one of the multiple memory portions having a lowest cost. In one embodiment, wherein the cost factor includes a replacement cost factor 1/N added to a least recently used (LRU) factor, where N is a number of parallel requests currently pending for the associated source agent. In one embodiment, wherein the cost factor is dynamically adjustable by a scaling factor to provide more or less weight to the cost factor.

In one aspect, a memory management device includes: a queue to store requests for access to a memory device managed by the memory management device; an eviction table to store a weight associated with each of multiple memory portions of the memory device, each of the multiple memory portions having an associated source agent that generates requests for data stored in the memory portion, wherein each weight is factored based on access history for the memory portion as well as a cost factor that indicates a latency impact on the associated source agent to replace the memory portion; and an eviction processor configured to initialize a count for one of the memory portions; adjust the count based on access to the one memory portion by the associated source agent; adjust the count based on a dynamic cost factor for the associated source agent; and compare the count to counts for others of the multiple memory portions to determine which memory portion to evict in response to an eviction trigger for the memory device.

In one embodiment, wherein the memory device comprises a DRAM (dynamic random access memory) resource for a host system. In one embodiment, wherein the eviction processor comprises a processor of a memory controller device. In one embodiment, wherein the DRAM is a highest level memory of a multilevel memory (MLM) system, wherein the eviction processor is to detect the eviction trigger in response to a page fault occurring in response to servicing a request from a cache of the MLM. In one embodiment, wherein the eviction processor is to identify the memory portion having a lowest cost to evict. In one embodiment, wherein the cost factor includes a replacement cost factor 1/N added to a least recently used (LRU) factor, where N is a number of parallel requests currently pending in the queue for the associated source agent. In one embodiment, wherein the cost factor is dynamically adjustable by a scaling factor to provide more or less weight to the cost factor.

In one aspect, an electronic device with a memory subsystem includes: an SDRAM (synchronous dynamic random access memory) including a memory array to store multiple memory portions, each of the multiple memory portions having an associated source agent that generates requests for data stored in the SDRAM, wherein each weight is computed based on access history for the memory portion as well as a cost factor that indicates a latency impact on the associated source agent to replace the memory portion; and a memory controller to control access to the SDRAM, the memory controller including a queue to store requests for access to the SDRAM; an eviction table to store a weight associated with each of multiple memory portions; and an eviction processor configured to initialize a count for one of the memory portions; adjust the count based on access to the one memory portion by the associated source agent; adjust the count based on a dynamic cost factor for the associated source agent; and compare the count to counts for others of the multiple memory portions to determine which memory portion to evict in response to an eviction trigger for the memory device; and a touchscreen display coupled to generate a display based on data accessed from the SDRAM.

In one embodiment, wherein the memory controller comprises a memory controller circuit integrated onto a host processor system on a chip (SoC). In one embodiment, wherein the SDRAM is a highest level memory of a multilevel memory (MLM) system, wherein the eviction processor is to detect the eviction trigger in response to a page fault occurring in response to servicing a request from a cache of the MLM. In one embodiment, wherein the eviction processor is to identify for eviction the memory portion having a lowest count. In one embodiment, wherein the cost factor includes a replacement cost factor 1/N added to a least recently used (LRU) factor, where N is a number of parallel requests currently pending in the queue for the associated source agent. In one embodiment, wherein the cost factor is dynamically adjustable by a scaling factor to provide more or less weight to the cost factor.

In one aspect, a method for managing eviction from a memory device includes: detecting an eviction trigger in a memory device, where the eviction trigger indicates one of multiple portions of memory should be removed from the memory device, each memory portion having an associated weight and an associated source agent that generates requests for data stored in the memory portion; identifying a memory portion having a most extreme weight, wherein each weight is computed based on access history for the memory portion and adjusted by a cost factor that indicates a latency impact on the associated source agent to replace the memory portion; and replacing the memory portion identified as having the most extreme weight, with a memory portion that triggered the eviction.

In one embodiment, wherein the memory device comprises a main memory resource for a host system. In one embodiment, wherein detecting the eviction trigger comprises detecting the eviction trigger with a memory controller device. In one embodiment, wherein detecting the eviction trigger comprises receiving a request from a lower-level memory requesting data that causes a miss in the memory device. In one embodiment, wherein identifying the memory portion having the most extreme weight comprises identifying the memory portion having a lowest cost to evict. In one embodiment, wherein the cost factor includes a replacement cost factor 1/N added to a least recently used (LRU) factor, where N is a number of parallel requests currently pending for the associated source agent. In one embodiment, wherein the cost factor is dynamically adjustable by a scaling factor to provide more or less weight to the cost factor.

In one aspect, a memory management device includes: a queue to store requests for access to a memory device managed by the memory management device; an eviction table to store a weight associated with each of multiple memory portions of the memory device, each of the multiple memory portions having an associated source agent that generates requests for data stored in the memory portion, wherein each weight is factored based on access history for the memory portion as well as a cost factor that indicates a latency impact on the associated source agent to replace the memory portion; and an eviction processor configured to detect an eviction trigger indicating one of the multiple memory portions should be removed from the memory device; identify a memory portion having a most extreme weight in the eviction table; and, replace the memory portion identified as having the most extreme weight with a memory portion that triggered the eviction.

In one embodiment, wherein the memory device comprises a DRAM (dynamic random access memory) resource for a host system. In one embodiment, wherein the eviction processor comprises a processor of a memory controller device. In one embodiment, wherein the DRAM is a highest level memory of a multilevel memory (MLM) system, wherein the eviction processor is to detect the eviction trigger in response to a page fault occurring in response to servicing a request from a cache of the MLM. In one embodiment, wherein the eviction processor is to identify the memory portion having a lowest cost to evict. In one embodiment, wherein the cost factor includes a replacement cost factor 1/N added to a least recently used (LRU) factor, where N is a number of parallel requests currently pending in the queue for the associated source agent. In one embodiment, wherein the cost factor is dynamically adjustable by a scaling factor to provide more or less weight to the cost factor.

In one aspect, an electronic device with a memory subsystem includes: an SDRAM (synchronous dynamic random access memory) including a memory array to store multiple memory portions, each of the multiple memory portions having an associated source agent that generates requests for data stored in the SDRAM, wherein each weight is computed based on access history for the memory portion as well as a cost factor that indicates a latency impact on the associated source agent to replace the memory portion; and a memory controller to control access to the SDRAM, the memory controller including a queue to store requests for access to the SDRAM; an eviction table to store a weight associated with each of multiple memory portions; and an eviction processor configured to detect an eviction trigger indicating one of the multiple memory portions should be removed from the SDRAM; identify a memory portion having a most extreme weight in the eviction table; and, replace the memory portion identified as having the most extreme weight with a memory portion that triggered the eviction; and a touchscreen display coupled to generate a display based on data accessed from the SDRAM.

In one embodiment, wherein the memory controller comprises a memory controller circuit integrated onto a host processor system on a chip (SoC). In one embodiment, wherein the cost factor includes a replacement cost factor 1/N added to a least recently used (LRU) factor, where N is a number of parallel requests currently pending in the queue for the associated source agent. In one embodiment, wherein the cost factor is dynamically adjustable by a scaling factor to provide more or less weight to the cost factor. In one embodiment, wherein the SDRAM is a highest level memory of a multilevel memory (MLM) system, wherein the eviction processor is to detect the eviction trigger in response to a page fault occurring in response to servicing a request from a cache of the MLM. In one embodiment, wherein the eviction processor is to identify the memory portion having a lowest cost to evict.

In one aspect, an article of manufacture comprising a computer readable storage medium having content stored thereon, which when accessed causes a computing device to perform operations for managing eviction from a memory device, including: initializing a count for one of multiple memory portions in a memory device, including associating the count with a source agent that accesses the one memory portion; adjusting the count based on access to the one memory portion by the associated source agent; adjusting the count based on a dynamic cost factor for the associated source agent, where the dynamic cost factor represents a latency impact to performance of the source agent to replace the memory portion; and comparing the count to counts for others of the multiple portions to determine which memory portion to evict in response to an eviction trigger for the memory device. Any embodiment described with respect to the method for managing eviction from a memory device can also apply to the article of manufacture.

In one aspect, an apparatus for managing eviction from a memory device including: means for initializing a count for one of multiple memory portions in a memory device, including associating the count with a source agent that accesses the one memory portion; means for adjusting the count based on access to the one memory portion by the associated source agent; means for adjusting the count based on a dynamic cost factor for the associated source agent, where the dynamic cost factor represents a latency impact to performance of the source agent to replace the memory portion; and means for comparing the count to counts for others of the multiple portions to determine which memory portion to evict in response to an eviction trigger for the memory device. Any embodiment described with respect to the method for managing eviction from a memory device can also apply to the apparatus.

In one aspect, an article of manufacture comprising a computer readable storage medium having content stored thereon, which when accessed causes a computing device to perform operations for managing eviction from a memory device, comprising: detecting an eviction trigger in a memory device, where the eviction trigger indicates one of multiple portions of memory should be removed from the memory device, each memory portion having an associated weight and an associated source agent that generates requests for data stored in the memory portion; identifying a memory portion having a most extreme weight, wherein each weight is computed based on access history for the memory portion and adjusted by a cost factor that indicates a latency impact on the associated source agent to replace the memory portion; and replacing the memory portion identified as having the most extreme weight, with a memory portion that triggered the eviction. Any embodiment described with respect to the method for managing eviction from a memory device can also apply to the article of manufacture.

In one aspect, an apparatus for managing eviction from a memory device includes: means for detecting an eviction trigger in a memory device, where the eviction trigger indicates one of multiple portions of memory should be removed from the memory device, each memory portion having an associated weight and an associated source agent that generates requests for data stored in the memory portion; means for identifying a memory portion having a most extreme weight, wherein each weight is computed based on access history for the memory portion and adjusted by a cost factor that indicates a latency impact on the associated source agent to replace the memory portion; and means for replacing the memory portion identified as having the most extreme weight, with a memory portion that triggered the eviction. Any embodiment described with respect to the method for managing eviction from a memory device can also apply to the apparatus.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

What is claimed is:

1. A method for managing eviction from a memory device, comprising:
initializing a count for one of multiple memory portions in a memory device, including associating the count with a source agent that accesses the one memory portion;
adjusting the count based on access to the one memory portion by the associated source agent;
adjusting the count based on a dynamic cost factor for the associated source agent, where the dynamic cost factor represents a latency impact to performance of the source agent to replace the memory portion; and
comparing the count to counts for others of the multiple portions to determine which memory portion to evict in response to an eviction trigger for the memory device.

2. The method of claim 1, wherein the memory device comprises a main memory resource for a host system.

3. The method of claim 2, wherein the comparing comprise comparing with a memory controller device.

4. The method of claim 2, wherein initializing the count comprises initializing the count in response to receiving a request from a lower-level memory requesting data.

5. The method of claim 1, wherein comparing the count further comprises identifying for eviction one of the multiple memory portions having a lowest cost.

6. The method of claim 5, wherein the cost factor includes a replacement cost factor 1/N added to a least recently used (LRU) factor, where N is a number of parallel requests currently pending for the associated source agent.

7. The method of claim 1, wherein the cost factor is dynamically adjustable by a scaling factor to provide more or less weight to the cost factor.

8. A memory management device, comprising:
a queue to store requests for access to a memory device managed by the memory management device;
an eviction table to store a weight associated with each of multiple memory portions of the memory device, each of the multiple memory portions having an associated source agent that generates requests for data stored in the memory portion, wherein each weight is factored based on access history for the memory portion as well as a cost factor that indicates a latency impact on the associated source agent to replace the memory portion; and
an eviction processor configured to initialize a count for one of the memory portions; adjust the count based on access to the one memory portion by the associated source agent; adjust the count based on a dynamic cost factor for the associated source agent; and compare the count to counts for others of the multiple memory portions to determine which memory portion to evict in response to an eviction trigger for the memory device.

9. The memory management device of claim 8, wherein the memory device comprises a DRAM (dynamic random access memory) resource for a host system.

10. The memory management device of claim 9, wherein the eviction processor comprises a processor of a memory controller device.

11. The memory management device of claim 9, wherein the DRAM is a highest level memory of a multilevel memory (MLM) system, wherein the eviction processor is to detect the eviction trigger in response to a page fault occurring in response to servicing a request from a cache of the MLM.

12. The memory management device of claim 8, wherein the eviction processor is to identify the memory portion having a lowest cost to evict.

13. The memory management device of claim 12, wherein the cost factor includes a replacement cost factor 1/N added to a least recently used (LRU) factor, where N is a number of parallel requests currently pending in the queue for the associated source agent.

14. The memory management device of claim 8, wherein the cost factor is dynamically adjustable by a scaling factor to provide more or less weight to the cost factor.

15. An electronic device with a memory subsystem, comprising:
an SDRAM (synchronous dynamic random access memory) including a memory array to store multiple memory portions, each of the multiple memory portions having an associated source agent that generates requests for data stored in the SDRAM, wherein each weight is computed based on access history for the memory portion as well as a cost factor that indicates a latency impact on the associated source agent to replace the memory portion; and
a memory controller to control access to the SDRAM, the memory controller including
a queue to store requests for access to the SDRAM;
an eviction table to store a weight associated with each of multiple memory portions; and
an eviction processor configured to initialize a count for one of the memory portions; adjust the count based on access to the one memory portion by the associated source agent; adjust the count based on a dynamic cost factor for the associated source agent; and compare the count to counts for others of the multiple memory portions to determine which memory portion to evict in response to an eviction trigger for the memory device; and
a touchscreen display coupled to generate a display based on data accessed from the SDRAM.

16. The electronic device of claim 15, wherein the memory controller comprises a memory controller circuit integrated onto a host processor system on a chip (SoC).

17. The memory management device of claim 9, wherein the SDRAM is a highest level memory of a multilevel memory (MLM) system, wherein the eviction processor is to detect the eviction trigger in response to a page fault occurring in response to servicing a request from a cache of the MLM.

18. The electronic device of claim 15, wherein the eviction processor is to identify for eviction the memory portion having a lowest count.

19. The electronic device of claim 15, wherein the cost factor includes a replacement cost factor 1/N added to a least recently used (LRU) factor, where N is a number of parallel requests currently pending in the queue for the associated source agent.

20. The electronic device of claim 15, wherein the cost factor is dynamically adjustable by a scaling factor to provide more or less weight to the cost factor.
